(19) United States
(12) Patent Application Publication
(10) Pub. No.: US 2025/0232078 A1
(43) Pub. Date: Jul. 17, 2025

(54) SYSTEMS AND METHODS FOR HIGH FIDELITY FAST SIMULATION OF HUMAN IN THE LOOP HUMAN IN THE PLANT (HIL-HIP) SYSTEMS

(71) Applicants: Ayan Banerjee, Gilbert, AZ (US); Sandeep Gupta, Phoenix, AZ (US)

(72) Inventors: Ayan Banerjee, Gilbert, AZ (US); Sandeep Gupta, Phoenix, AZ (US)

(73) Assignee: Arizona Board of Regents on Behalf of Arizona State University, Tempe, AZ (US)

(21) Appl. No.: 19/019,145

(22) Filed: Jan. 13, 2025

Related U.S. Application Data
(60) Provisional application No. 63/620,616, filed on Jan. 12, 2024.

(51) Int. Cl. G06F 30/18

(52) U.S. Cl. CPC G06F 30/18

(57) ABSTRACT

Examples of a simulation framework are provided to evaluate time varying systems using a piecewise linear time invariant simulation (PLIS) approach. The simulation framework can be configured for an artificial pancreas wireless network system that controls blood glucose in Type 1 Diabetes patients with time varying properties such as physiological changes associated with psychological stress and meal patterns.

### CROSS REFERENCE TO RELATED APPLICATIONS

This is a non-provisional application that claims benefit to U.S. Provisional Application Ser. No. 63/620,616, filed on Jan. 12, 2024, which is herein incorporated by reference in its entirety.

### GOVERNMENT SUPPORT

This invention was made with government support under N6600120C4020 awarded by the DARPA AMP. The government has certain rights in the invention.

### FIELD

The present disclosure generally relates to computing technologies including simulation systems and sensor networks; and in particular to a simulation framework for an artificial pancreas wireless network system.

### BACKGROUND

Modern day safety critical human in the plant (HIP) infrastructure such as artificial pancreas, and autonomous cars, typically work through integration of a wireless network with a physical plant often including a human for sensing and actuation. Irrespective of autonomy level, a human manager, human in the loop (HIL), often makes configuration changes to achieve the best performance. The simulation of the integration of a wireless mobile network (WMN) driven control system with the HIL-HIP architecture is essential for performance, safety, and resource efficacy analysis.

The tight coupling of the WMN with the human manager/user results in frequent changes in control configurations as well as changes in the physical system properties. Consequently, the WMN exhibits time-varying characteristics. In addition, non-linearities in simulation arise from the time variance in the wireless networks when integrated with the HIL-HIP architecture physical systems under dynamic contexts, leading to simulation slowdown.

It is with these observations in mind, among others, that various aspects of the present disclosure were conceived and developed.

### BRIEF DESCRIPTION OF THE DRAWINGS

FIG. 1 is a simplified system model illustration for a wireless network controlled plant where the human is both the configuration manager and a component of the plant.

FIG. 2 is a graph illustrating a simulation strategy to tackle non-linearities induced by time variance of model coefficients where the zero order hold strategy assumes constant value for A_{i,k}(t) at each time sub-interval.

FIG. 3 is a graph illustrating variation of cortisol level over time throughout the day of an individual with T1D under TSST.

FIG. 4 is a simplified diagram of an example computing device or system for implementing functionality described herein.

Corresponding reference characters indicate corresponding elements among the view of the drawings. The headings used in the figures do not limit the scope of the claims.

### DETAILED DESCRIPTION

The present disclosure relates to examples of a simulation framework to evaluate time varying systems using a piecewise linear time invariant simulation (PLIS) approach. The simulation framework can be configured for an artificial pancreas wireless network system that controls blood glucose in Type 1 Diabetes patients with time varying properties such as physiological changes associated with psychological stress and meal patterns.

More specifically, non-linearities in simulation arise from the time variance in wireless mobile networks when integrated with human in the loop, human in the plant (HIL-HIP) physical systems under dynamic contexts, leading to simulation slowdown. Time variance is handled by deriving a series of piece wise linear time invariant simulations (PLIS) in intervals, which are then concatenated in time domain. In the present disclosure, a formal analysis of the impact of discretizing time-varying components in wireless network-controlled HIL-HIP systems on simulation accuracy and speedup is conducted, and an evaluation of trade-offs with reliable guarantees is presented. An accurate simulation framework is described for an artificial pancreas wireless network system that controls blood glucose in Type 1 Diabetes patients with time varying properties such as physiological changes associated with psychological stress and meal patterns. PLIS approach achieves accurate simulation with >2.1 times speedup than a non-linear system simulation for the given dataset.

### 1 Introduction

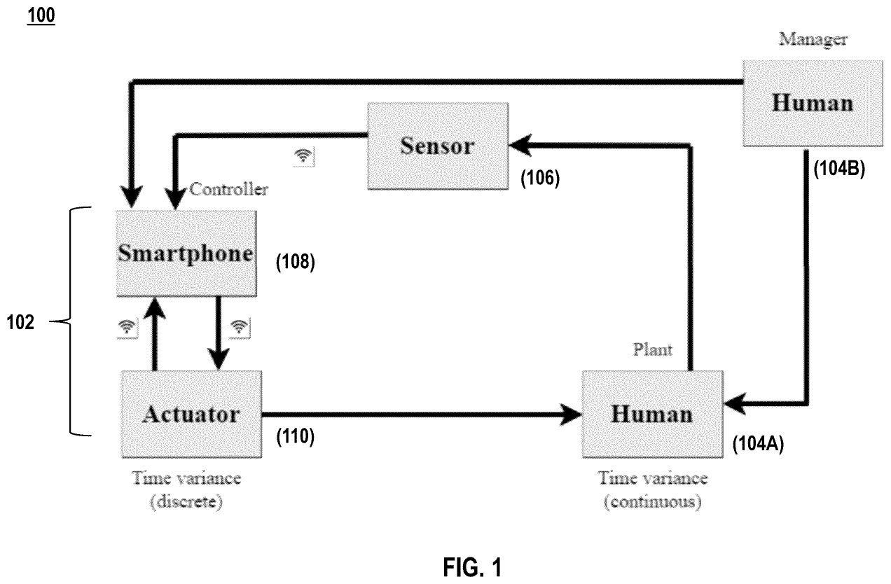

Referring to FIG. 1, modern day safety critical human in the plant (HIP) infrastructure such as an artificial pancreas and autonomous cars, can work through integration of a wireless network (102) with a physical plant (104A) often including a human for sensing and actuation. In FIG. 1, an example system 100 for human in the plant (HIP) infrastructure is shown including at least one wireless network 102, one or more humans 104 (human in the loop, human in the plant (HIL-HIP)), at least one sensor 106, a mobile device 108 such as a smartphone, and an actuator 110.

Irrespective of autonomy level, a human manager (104B), human in the loop (HIL), often makes configuration changes to achieve the best performance. The simulation of the integration of a wireless mobile network (WMN) driven control system with the HIL-HIP architecture is essential for performance, safety, and resource efficacy analysis.

The tight coupling of the WMN with the human manager/user results in frequent changes in control configurations as well as changes in the physical system properties. Consequently, the WMN exhibits time-varying characteristics. The time varying properties of the discrete control software executed by the WMN changes in-frequently and can be tackled using an event driven simulation strategy. As such simulation of time varying physical dynamics through an event driven simulation strategy will be prohibitively expensive since it will result in a simulation time step that is infinitesimally small.

Traditionally, a time varying system is treated as a non-linear system, and complex non-linear solvers are used for simulation which may require significant execution time. This prevents their usage in applications such as digital twins, forward safety analysis or online observer. One possible simplification is modeling the time varying system as a concatenation of several piecewise time invariant systems. The simulation time interval [0, T] is subdivided into sub-intervals starting at times τj. At the start of each time interval, a zero order hold assumption of the time varying parameters is undertaken, and the simulation is performed using linear system solution techniques such as Euler method. Although this enables the usage of simpler solvers and hence saves time, it is believed that no prior work exists that bounds the error rate of such piecewise time invariant approximations.

TABLE 1
Other Works

| | | | Accuracy | |
|---|---|---|---|---|
| | System | Method | Guarantees | Metrics for Results |
| | Heat exchange ventilation system | Reduced order polynomial ODE | No | Low RMSE and error rate. |
| | Recharge areas of Karst system | Reduced order polynomial ODE | No | Reproduction of recharge areas of |
| | | | | the Karst system |
| | Compartmental Model | Physics Informed Neural Networks. | No | Simulation accuracy |
| | A nonlinear system | Piecewise-polynomial representations. | No | Average speedup w.r.t full model. |
| | Ventilation flow system | ODE-45 solver | No | Simulation accuracy |
| This work | Artificial Pancreas | piecewise linear time invariant | Yes | Speed up accuracy tradeoff |

By the present inventive concept described herein, a framework is developed and described to evaluate the simulation error of piecewise linear time invariant simulation (PLIS) approach. A closed form solution is derived for the propagation of error in model coefficients through the system dynamics and provide a pathway to derive time stamps of each simulation piece such that the simulation error can be kept within pre-specified bounds. The inventive framework is compared with the PLIS simulator with two other types of simulation: a) ORACLE, which considered the non-linear system in presence of time variant dynamics, and b) Koopman simulator, that approximates the non-linear dynamical system as a higher order linear system. The execution of PLIS is shown on three different control approaches using WMN for the artificial pancreas case study. PLIS can be configured to achieve the similar simulation accuracy as ORACLE or Koopman with at least 2.1 and at most 8 times speedup.

### 2 Other Works

Time-varying system dynamics can be simulated by solving nonlinear ordinary differential equations (ODE). Recent advancements take advantage of data driven supervised learning, such as NeuralODE, or Euler-physics induced neural networks. Such methods are usually slow and depending on the simulation time step. Moreover, no accuracy guarantees are provided.

Time varying systems can be represented with reduced-order polynomial models of the system which are then used to simulate the essential characteristics of the system and have demonstrated considerable improvement over traditional ODE solvers showing 6-9 times speed up in simulating electrical circuits and applied to ventilator simulation and hydrological Karst model. However, these works are application specific and do not provide a closed form relation of speed-up with accuracy.

In contrast, the examples of the present disclosure show a general time varying system simulation framework with closed form speedup and accuracy tradeoffs from which error bounds can be derived.

### 3 Simulation Approach

The configuration of the WMN (FIG. 1) is given by a set of p state variables Y∈Z^{p}, Z is the set of natural numbers. The configurations Y(t) are a function of time. The plant dynamics is represented using the set of n state variables X∈Rⁿ, where R is the set of real numbers. The dynamics are time varying given by—

$$\frac{d X ( t )}{d t} = A ( t ) X ( t ) + B ( t ) u ( t ) , \qquad ( 1 )$$

where A(t) is n×n and B(t) is n×m time varying parameters of the system and u(t) is a m×1 vector of inputs obtained from the WMN. u(t)=g(X, Y) is a function g(.,.): (Z^{p}, R^{m})→R^{m} of the WMN configuration Y and the current plant state X to the m dimensional real space representing the computing algorithm.

Input modeling: In this disclosure we consider the step input i.e., u(t)=a:a∈R, if t>0, else u(t)=0. The most common type of inputs are square wave inputs. We assume that the wave width of the square wave will be larger than a simulation time step. Without loss in generality we can then assume u(t) to be a step function since the analysis can be limited to the time window when all step inputs have already executed their leading edge.

A trajectory ξ is a function from a set [0, T], T∈R^{≥0}, denoting time and WMN configurations Y(t) to a compact set of values ∈R. Each trajectory is the output of the physical system model M in the form of Eqn. 1 for a WMN configuration Y and the algorithm g(., .). Concatenation of q output trajectories over time ξ(Y(t₀), t₁−t₀)ξ(Y(t₁), t₂−t₁) . . . ξ(Y(t_{q-1}), t_{q}−t_{q-1}) is a trace [symbol] .

Definition 3.1. ORACLE Simulator: The oracle simulator Σ_{O} has access to: a) closed form function A_{i,j}(t)=ƒ_{i,j}^{A}(t), and B_{i,j}(t)=ƒ_{i,j}^{B}(t) for each time varying model coefficient of the plant, and b) all WMN configuration changes of the future. It uses non-linear ODE solvers to evaluate the traces.

Definition 3.2. Koopman Simulator: The Koopman simulator Σₖ has access to a high dimensional linear time invariant system, referred to as Koopman LTI, —

$$\frac{d {X}_{k} ( t )}{d t} = {A}_{k} {X}_{k} ( t ) + {B}_{k} u ( t ) , \qquad ( 2 )$$

where Aₖ(nₖ×nₖ) and Bₖ(nₖ×m) are constants, where nₖ>>n, and Xₖ(t)=M_{ƒ}(X(t)) is a measurement function. The simulator obtains an estimate of Xₑ(t) by computing the pre-image M_{ƒ}⁻¹ of the measurement function. The Koopman LTI is developed so that distₑ(Xₑ(t), X(t))<ϵₖ, where ϵₖ is the error of the Koopman transformation operation. In the present disclosure, the discrete mode decomposition (DMD) method can be utilized to obtain the Koopman transforms of the non-linear Eqn. 1.

Definition 3.3. Piece-wise Linear-Invariant Simulator (PLIS) divides the time interval [0, T] into sub-intervals τⱼ, j∈{1 . . . s} with τₛ=T, τⱼ<τⱼ₊₁∀j, such that in a time interval τⱼ the plant follows—

$$\frac{d {X}_{P} ( t )}{d t} = {A}^{j} {X}_{P} ( t ) + {B}^{j} u ( t ) , \qquad ( 3 )$$

where A^{j}=ƒₐ(A(t), τⱼ) (B^{j}=ƒₐ(B(t), τⱼ)), is zero order hold approximation of A(t) B(t) in the time interval τⱼ, and Xₚ is an estimated state vector.

Problem 1. PLIS design Problem: Given a trace [symbol] , find a PLIS Σₚ={τⱼ, A^{j}, B^{j}}: (τₛ=T)∩τⱼ<τⱼ₊₁∀j∩dist(ξₚ(Y(τⱼ), τⱼ₊₁−τⱼ)), ξ(Y(τⱼ),τⱼ₊₁−τⱼ))<ϵₚ∩dist( [symbol] , [symbol] )<ψₚ, with error ϵₚ in trajectory and ψₚ in trace. Here ξₚ and Tₚ are the trajectories and traces for the PLIS.

This is a dual error analysis approach. We not only minimize the error in trajectory between two events, but also minimize the error for the entire trace including multiple WMN control events.

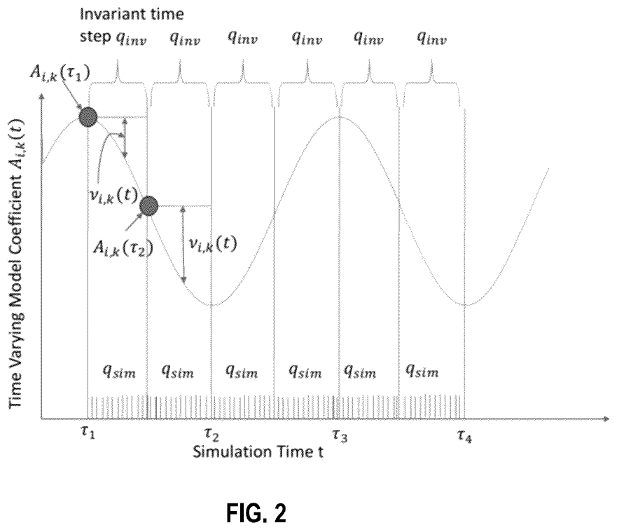

PLIS Design Solution: For solving PLIS we need to find the function ƒₐ, i.e., the zero order hold approximations of the coefficients. We assume that ƒₐ(A(t), τⱼ)=A(τⱼ), ∀t∈{τⱼ, τⱼ₊₁} and ƒₐ(B(t), τⱼ)=B(τⱼ), ∀t∈{τⱼ, τⱼ₊₁} (FIG. 2). The PLIS simulation divides the time interval [0, T] into sub-intervals τⱼ (qᵢₙᵥ shown in FIG. 2) such that the propagated error from the coefficients to the trajectories is less than ϵₚ, and to the overall trace is less than ψₚ. To this effect, we define two time steps: a) simulation time step, qₛᵢₘ, is the fine grain division of each sub-interval so that the assumed time invariant dynamics in each sub interval can be computed using the Euler method limiting the error within tolerance levels, and b) Invariant time step qᵢₙᵥ, (FIG. 2) determines the sub-intervals where the time invariance assumption results in a simulation error that is less than ϵₚ for every trajectory, and less than ψₚ for the entire trace, i.e., τⱼ₊₁−τⱼ=qᵢₙᵥ∀ⱼ.

Error propagation: For any element A_{i,k}∈A(B_{i,k}∈B), the true value can be represented using an error value A_{i,k}(t)=A_{i,k}(τⱼ)+v_{i,k}(t). From Eqn. 1, we obtain the following error propagation model for an element xₚⁱ∈Xₚ—

$$\frac{d {x}_{p}^{i}}{d y} = {\sum }_{k = 1}^{n} {A}_{i , k} ( {τ}_{j} ) {x}_{p}^{k} + {\sum }_{k = 1}^{m} {B}_{i , k} ( {τ}_{j} ) {u}^{k} ( t ) + {\sum }_{k = 1}^{n} {A}_{i , k} {μ}_{k} + \frac{d {μ}_{i}}{d t} , \qquad ( 4 )$$

where μᵢ are extra state variables whose evolution is governed by a linear time invariant system in Eqn. 5:

$$\frac{d μ}{d t} = {v}_{A} {X}_{P} ( t ) + {v}_{B} u ( t ) , \qquad ( 5 )$$

and where μ is the vector containing μᵢ, v_{A} is an n×n matrix containing all error values v_{i,k} associated with A(t) matrix. Similarly v_{B} is an n×m matrix containing all error values v_{i,k}, for the B(t) matrix.

Eqn. 4 expresses PLIS solution as a congregation of: a) state space evolution assuming zero order hold of model coefficients, b) propagation of errors of the zero order hold assumption through the unperturbed system, and c) a new state space (Eqn. 5) defined by the errors in the model coefficients. The overall solution is a linear-time-invariance (LTI) system with an extended state space of Z=Xₚ∪μ given by—

$$\frac{d H}{d t} = {A}_{e x} H + {B}_{e x} u , H = [ \begin{matrix}{X}_{p} \\ μ\end{matrix} ] , {A}_{e x} = [ \begin{matrix}A ( {τ}_{j} ) + {v}_{A} & A ( {τ}_{j} ) \\ v & {Θ}_{n n}\end{matrix} ] , \\ {B}_{e x} = [ \begin{matrix}B ( {τ}_{j} ) + {v}_{B} \\ {Θ}_{n n}\end{matrix} ] \qquad ( 6 )$$

where Θₙₙ is an n×n matrix of zeros and Θₙₘ is an n×m matrix of zeros. H is a 2n×1 vector, Aₑₓ is a 2n×2n matrix, Bₑₓ is a 2n×m matrix. By solving this LTI system we can determine the error and use the maximum error to obtain the sub-interval [τⱼ, τⱼ₊₁].

Estimate of v_{i,k}: We assume the most conservative error in the zero order hold assumption where

$${v}_{i , k} ( t ) = [ {max}_{∀ t ∈ [ {τ}_{j} - {τ}_{j + 1} ]} \frac{d {A}_{i , k} ( t )}{dt} ] t ,$$

i.e. we take the maximum slope of A_{i,k}(t) in the interval [τⱼ; τⱼ₊₁] and assume that v_{i,k} is linear. To ensure that the true error in zero order hold never exceeds this limit, we have to consider time sub-intervals such that A_{i,k}(t) are monotonously increasing or decreasing. This can be achieved by examining the differential of each time varying model coefficient and setting the qᵢₙᵥ to the minimum time required for the slope of any A_{i,k} to change resulting in the following constant for v_{i,k}—

$${v}_{i , k} = [ {max}_{∀ t ∈ [ {τ}_{j} , {τ}_{j + 1} ]} \frac{d {A}_{i , k} ( t )}{d t} ] {q}_{inv} . \qquad ( 7 )$$

Error bound and invariant time step estimation: Replacing v_{i,k} in Eqn. 6 and solving for H using the traditional Euler method gives the temporal evolution of H in terms of qᵢₙᵥ. The difference between the first n elements of H and the estimate of Xₚ by the PLIS gives an upper bound of simulation error. This is an upper bound because when selecting the approximation of A_{i,k}, we assume the maximum slope with which A_{i,k}(t) varies over time t. By changing the qᵢₙₜ the error can be modulated such that the error in trajectory is within ϵₚ and the error in trace is less than ψₚ.

### 4 Evaluation

The evaluation metrics, the performance results and comparison between the PLIS and ORACLE shall now be discussed.

Artificial Pancreas (AP) System: This system includes a continuous glucose monitor (CGM) that senses glucose, and a controller that computes insulin delivery which is executed through an infusion pump. The glucose insulin dynamics is given by the Bergman Minimal Model (BMM):

$$[ \begin{matrix}i \\ {i}_{s} \\ G\end{matrix} ] = A [ \begin{matrix}i \\ {i}_{s} \\ G\end{matrix} ] + B [ \begin{matrix}{i}_{b} \\ 0 \\ {u}_{2}\end{matrix} ] , A = [ \begin{matrix}- n & 0 & 0 \\ {p}_{2} & - {p}_{1} & 0 \\ 0 & {G}_{b} & - p 3\end{matrix} ] , B = [ \begin{matrix}{p}_{4} \\ 0 \\ 1 / Vol\end{matrix} ] \qquad ( 8 )$$

The input vector u(t) consists of basal insulin level i_{b} and the glucose appearance rate u₂. The state vector X(t) has the blood insulin level i, the interstitial insulin level iₛ, and the blood glucose level G. p₁, p₂, p₃, p₄, n, and 1/V_{O}I are all patient specific coefficients.

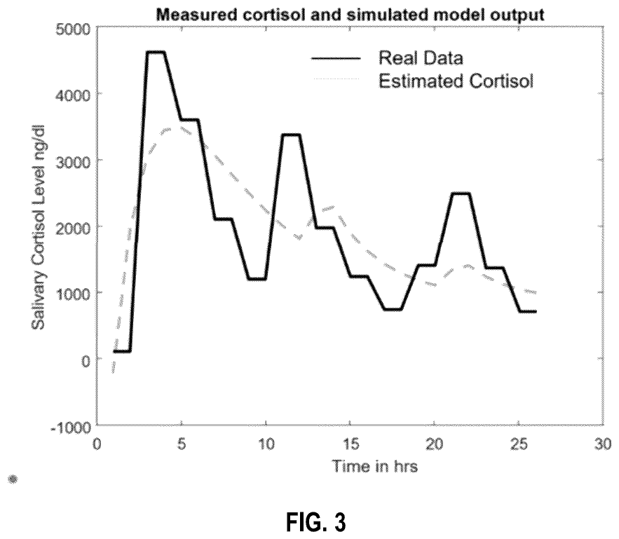

Time variance: The insulin sensitivity (SI) of a person varies with psychological stress throughout the day. SI is the parameter p₃/p₄. The psychological stress can be measured using the oral cortisol level of a person. SI has a negative linear correlation with cortisol which in turn varies over time (FIG. 3). The time varying cortisol level C(t) can be modeled using the following equation:

$$C ( t ) = \frac{{K}_{p}}{{T}_{p 2} - {T}_{p 1}} [ {e}^{\frac{- t}{{T}_{p 1}}} - {e}^{\frac{- t}{{T}_{p 1}}} + \frac{{T}_{z}}{{T}_{d}} [ \frac{1}{{T}_{p 1}} {e}^{\frac{- ( t - {T}_{d} )}{{T}_{p 1}}} - \frac{1}{{T}_{p 2}} {e}^{\frac{- ( t - {T}_{d} )}{{T}_{p 2}}} ] ] \qquad ( 9 )$$

The SI is a linear function of the cortisol C(t) and is given by a linear regression function

$${p}_{3} ( t ) = {p}_{4} \times ( η C ( t ) + β ) , \qquad ( 10 )$$

where η and β are constants. The time varying version of Eqn. 8 is obtained by replacing p₃ by Eqn. 10.

AP Dataset: Through collaboration with clinical partners access was provided to cortisol measurements (FIG. 3) during a day of induced psychological stress through the Trier social stress test (TSST). The TSST was administered twice, once at 8 am and then again at 2:30 pm. Salivary cortisol level was measured at intervals of 30 mins. 12 subjects with Type 1 Diabetes were recruited. These subjects were using a Tandem Control IQ and MPC. Each subject was monitored for 3 weeks, with cortisol data collected only in one day. The parameters of Eqn. 9 were derived from the data with T_{d}=15 mins. The computed poles and zeros are Tₚ₁=2.5 hrs, Tₚ₂=5 hrs, T_{z}=1.5 hrs. The Kₚ=1.215 ng/dl value is obtained by fitting a linear regression model on the maximum value of cortisol in each cortisol wave in FIG. 3.

AP control systems: Three control strategies are used:
a) Proportional integrative and derivative (PID) controller.
b) Model predictive control (MPC)—uses a model of the plant to predict future glucose values and then derives the appropriate insulin output to optimize an objective function. The model used in the subject MPC implementation is Eqn. 8. The prediction and control windows were set to 60 mins and 30 mins respectively as per implementation documentation in Control IQ AP.
c) Optimal control with Bayesian meal prediction, is a meal to meal controller that uses the linearized BMM and Linear Quadratic Gaussian (LQG) optimal control strategy to reach the set point before the next meal is taken. The meal patterns of each individual patient were modeled as large, medium and small meals. A Markov chain was implemented to represent the meal intake pattern of a patient and to predict the next meal size. The linearized patient model without bolus is then simulated to derive the largest possible CGM variation. This is then used to derive the set point for the current meal.

ORACLE simulator: The oracle simulator uses the actual times of the real events in the dataset and simulates using an event-driven approach. In this approach, the exact timing of each event is known and the simulation is stopped. It is then reconfigured with the changes given by the HIL user, and the simulation is restarted. In between two events, the simulation uses the time varying version of Eqn. 8 and solves it using ODE45.

Koopman Simulator: The Koopman simulator is very similar to the ORACLE simulator except that the plant physical dynamics are approximated with a higher order linear model. The CGM and insulin data from the AP dataset was used and the DMD reduced order linear system identification strategy was executed to obtain a 13 order system. The Koopman operators for the 13 order system was obtained using the Koopman extracted code provided by the seminal publication which connects DMD with Koopman theory. The DMD also gives the inverse measurement functions M_{ƒ}⁻¹ that converts the 13 order system back to the 3 order system that directly correlates with the glucose dynamics shown in Eqn. 8.

PLIS Implementation: The PLIS implementation uses qᵢₙᵥ derived from Eqn. 7, and the sim error bounding strategy described in Section 3. The only time varying parameter is the insulin sensitivity p₃. The value of qᵢₙᵥ is obtained for ϵₚ of [2%, 5% and 10%] and the ψₚ of [5%, 10%, and 15%].

To determine the value of qᵢₙᵥ Algorithm 1 below can be followed. For a given ϵₚ and ψₚ, we first choose a large qᵢₙᵥ. We then compute the maximum slope of C(t) and compute the A(τⱼ) and B(τⱼ) matrices. We then simulate H and Xₚ following equations 6 and 3. The difference between the first n elements of H and Xₚ is computed using the root mean square metric. If the maximum error is greater than ϵₚ then qᵢₙᵥ is reduced by a value d. After looping through all time intervals in [0, T], the overall error for the trace T is computed and compared with ψₚ. Again if the error is greater than ψₚ, the qᵢₙᵥ is reduced by d and the simulation is rerun. The simulation is stopped when both the trajectory error and trace error is satisfied by qᵢₙᵥ.

Algorithm 1 qᵢₙᵥ = Error_Bounded_Invariant_Time(ϵₚ, ψₚ)

| | |
|---|---|
| 1: | input A, B, and C(t), WMN control algorithm, |
| 2: | output Invariant Time Step qᵢₙᵥ |
| 3: | Set an initial qᵢₙᵥ and an initial value of d |
| 4: | while ∃τⱼ∀j ∈ {1ldotsT/qᵢₙᵥ} do |
| 5: | $Compute the maximum of \frac{dC ( t )}{dt} from Equation 9$ |
| 6: | Setup matrices A_{(τj)} and B_{τj} |
| 7: | Compute H from Equation 6 and Xₚ from Equation 3 |
| 8: | Compute root mean square error between the first n elements of H |
| | and Xₚ. |
| 9: | Set rₘₐₓ^{j} = maximum rmse out of all n rmses. |
| 10: | if rₘₐₓ > ϵₚ then |
| 11: | qᵢₙᵥ = qᵢₙᵥ − d |
| 12: | else |
| 13: | remove τⱼ from the set. |
| 14: | end if |
| 15: | end while |
| 16: | Total error E = Σ_{∀j}rₘ^{j}a |
| 17: | if E > ψₚ then |
| 18: | qᵢₙᵥ = qᵢₙᵥ − d |
| 19: | Rerun the while loop |
| 20: | else |
| 21: | Return qᵢₙᵥ |
| 22: | end if |

### Evaluation Metrics

a) Glycemic metrics: We compare the three simulators in terms of Time in range (TIR) i.e. 70≤CGM≤180, Time above range (TAR) i.e. CGM>180, and TIme below range (TBR) i.e. CGM<70.

$$b ) Optimality ratio : p = \frac{( mean ( {G}_{P} ) + mean ( {I}_{P} ) + mean ( ( {i}_{sP} ) )}{( mean ( {G}_{O} ) + mean ( {I}_{O} ) + mean ( ( {i}_{so} ) )} ,$$

is defined as ratio of the mean values of the glucose, plasma insulin and interstitial insulin estimates for the PLIS or Koopman simulator to the mean values of the same metrics for ORACLE simulator.
c) Simulation speedup Sₚ: is defined by the ratio of execution time of PLIS or Koopman simulator with respect to the ORACLE.

TABLE 2
Glycemic metrics.

| | Control | | | | | | |
|---|---|---|---|---|---|---|---|
| Approach | Method | TIR (%) | | TAR (%) | | TBR (%) | |
| ORACLE | PID | 69 | [±17] | 29 | [±18] | 2 | [±1.3] |
| | MPC | 76 | [±14] | 20 | [±15] | 4 | [±3] |
| | Bayesian | 83 | [±21] | 11 | [±8.2] | 6 | [±4] |
| Koopman | PID | 68 | [17] | 27 | [±16] | 5 | [±3] |
| | MPC | 76 | [17] | 22 | [±13] | 2 | [±3] |
| | Bayesian | 84 | [20] | 13 | [±6.1] | 3 | [±2] |
| PLIS ϵp = 3%, | PID | 68 | [±21] | 30 | [±19] | 2 | [±1.4] |
| ψp = 5% | MPC | 76 | [±17] | 21 | [±11] | 3 | [±2] |
| | Bayesian | 82 | [±24] | 13 | [±5] | 5 | [±2] |
| PLIS ϵp = 6%, | PID | 71 | [±27] | 36 | [±17] | 3 | [1.7] |
| ψp = 10% | MPC | 71 | [±16] | 28 | [±10] | 1± | [±0.5] |
| | Bayesian | 88 | [±21] | 9 | [±7] | 3 | [±1] |
| PLIS ϵₚ = 10%, | PID | 60 | [±30] | 31 | [±15] | 9 | [±4.1] |
| ψₚ = 15% | MPC | 82 | [±19] | 16 | [±6] | 2 | [±0.7] |
| | Bayesian | 74 | [±14] | 20 | [±14] | 6 | [±5] |

TABLE 3
Optimality and Speed up of simulation approaches.

| Approach | Control Method | Optimality ρ | Speedup Sₚ |
|---|---|---|---|
| Koopman | PID | 1.1 | 1.2 |
| | MPC | 1.15 | 1.1 |
| | Bayesian | 1.2 | 1.05 |
| PLIS ϵp = 3%, | PID | 1.12 | 2.1 |
| ψp = 5% | MPC | 1.16 | 2.6 |
| | Bayesian | 1.11 | 2.4 |
| PLIS ϵp = 5%, | PID | 1.14 | 3.5 |
| ψp = 10% | MPC | 1.21 | 4.1 |
| | Bayesian | 1.17 | 3.7 |
| PLIS ϵₚ = 10%, | PID | 1.23 | 7.4 |
| ψₚ = 15% | MPC | 1.31 | 8.3 |
| | Bayesian | 1.29 | 8.1 |

### Evaluation Results

Glycemic metrics under an WMN controller: Table 2 shows that the ORACLE, Koopman and PLIS ϵp=3%, ψp=5% all have very less difference in TIR, TAR, and TBR metrics. However, when the error margins of PLIS are relaxed then the WMN controller performance metrics deviate from the ORACLE. We also see that both the Koopman and the PLIS also have similar relative glycemic metrics across the controllers. For Koopman and all the PLIS variations, the PID performed worse than the MPC, with the Bayesian approach showing the best TIR.

Optimality w.r.t ORACLE: The optimality metric (Table 3) shows that the Koopman simulator is closest to the ORACLE. The PLIS is also close to the ORACLE and the Koopman for the PID controller. However, for MPC the PLIS is further from the ORACLE. Moreover, as the error margin is relaxed, PLIS goes further than the ORACLE. Speedup w.r.t ORACLE: The PLIS has the better speedup with respect to ORACLE than Koopman. The PLIS has 1.7 to 8 times speedup with respect to ORACLE. As the error margin is relaxed, the speedup increases while optimality reduces.

### 5 Non-Limiting Conclusions

Time variance is seen in practical deployments of wireless mobile networks (WMN) especially when humans are involved in decision making (human in the loop) and also participate as a component of the plant (human in the plant). Time variance introduces non-linearities in the system dynamics. In this disclosure, a theoretical framework is provided for evaluating the error bound for piecewise time invariant simulation. An algorithm is provided to bound simulation error within a bound while achieving speed up. Its execution is shown for a real world WMN simulation of the artificial pancreas mobile wireless control system.

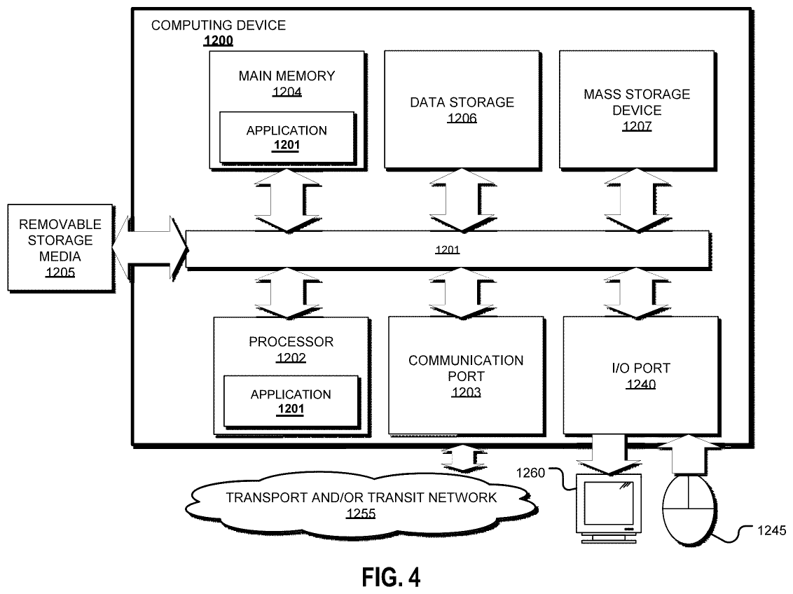

Exemplary Computing Device: Referring to FIG. 4, a computing device 1200 is illustrated which may can be configured, via one or more of an application 1211 or computer-executable instructions, to execute functionality described herein. More particularly, in some embodiments, aspects of the methods herein may be translated to software or machine-level code, which may be installed to and/or executed by the computing device 1200 such that the computing device 1200 is configured to execute functionality described herein. It is contemplated that the computing device 1200 may include any number of devices, such as personal computers, server computers, hand-held or laptop devices, tablet devices, multiprocessor systems, microprocessor-based systems, set top boxes, programmable consumer electronic devices, network PCs, minicomputers, mainframe computers, digital signal processors, state machines, logic circuitries, distributed computing environments, and the like.

The computing device 1200 may include various hardware components, such as a processor 1202, a main memory 1204 (e.g., a system memory), and a system bus 1201 that couples various components of the computing device 1200 to the processor 1202. The system bus 1201 may be any of several types of bus structures including a memory bus or memory controller, a peripheral bus, and a local bus using any of a variety of bus architectures. For example, such architectures may include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus also known as Mezzanine bus.

The computing device 1200 may further include a variety of memory devices and computer-readable media 1207 that includes removable/non-removable media and volatile/nonvolatile media and/or tangible media, but excludes transitory propagated signals. Computer-readable media 1207 may also include computer storage media and communication media. Computer storage media includes removable/non-removable media and volatile/nonvolatile media implemented in any method or technology for storage of information, such as computer-readable instructions, data structures, program modules or other data, such as RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium that may be used to store the desired information/data and which may be accessed by the computing device 1200. Communication media includes computer-readable instructions, data structures, program modules, or other data in a modulated data signal such as a carrier wave or other transport mechanism and includes any information delivery media. The term “modulated data signal” means a signal that has one or more of its characteristics set or changed in such a manner as to encode information in the signal. For example, communication media may include wired media such as a wired network or direct-wired connection and wireless media such as acoustic, RF, infrared, and/or other wireless media, or some combination thereof. Computer-readable media may be embodied as a computer program product, such as software stored on computer storage media.

The main memory 1204 includes computer storage media in the form of volatile/nonvolatile memory such as read only memory (ROM) and random access memory (RAM). A basic input/output system (BIOS), containing the basic routines that help to transfer information between elements within the computing device 1200 (e.g., during start-up) is typically stored in ROM. RAM typically contains data and/or program modules that are immediately accessible to and/or presently being operated on by processor 1202. Further, data storage 1206 in the form of Read-Only Memory (ROM) or otherwise may store an operating system, application programs, and other program modules and program data.

The data storage 1206 may also include other removable/non-removable, volatile/nonvolatile computer storage media. For example, the data storage 1206 may be: a hard disk drive that reads from or writes to non-removable, nonvolatile magnetic media; a magnetic disk drive that reads from or writes to a removable, nonvolatile magnetic disk; a solid state drive; and/or an optical disk drive that reads from or writes to a removable, nonvolatile optical disk such as a CD-ROM or other optical media. Other removable/non-removable, volatile/nonvolatile computer storage media may include magnetic tape cassettes, flash memory cards, digital versatile disks, digital video tape, solid state RAM, solid state ROM, and the like. The drives and their associated computer storage media provide storage of computer-readable instructions, data structures, program modules, and other data for the computing device 1200.

A user may enter commands and information through a user interface 1240 (displayed via a monitor 1260) by engaging input devices 1245 such as a tablet, electronic digitizer, a microphone, keyboard, and/or pointing device, commonly referred to as mouse, trackball or touch pad. Other input devices 1245 may include a joystick, game pad, satellite dish, scanner, or the like. Additionally, voice inputs, gesture inputs (e.g., via hands or fingers), or other natural user input methods may also be used with the appropriate input devices, such as a microphone, camera, tablet, touch pad, glove, or other sensor. These and other input devices 1245 are in operative connection to the processor 1202 and may be coupled to the system bus 1201, but may be connected by other interface and bus structures, such as a parallel port, game port or a universal serial bus (USB). The monitor 1260 or other type of display device may also be connected to the system bus 1201. The monitor 1260 may also be integrated with a touch-screen panel or the like.

The computing device 1200 may be implemented in a networked or cloud-computing environment using logical connections of a network interface 1203 to one or more remote devices, such as a remote computer. The remote computer may be a personal computer, a server, a router, a network PC, a peer device or other common network node, and typically includes many or all of the elements described above relative to the computing device 1200. The logical connection may include one or more local area networks (LAN) and one or more wide area networks (WAN), but may also include other networks. Such networking environments are commonplace in offices, enterprise-wide computer networks, intranets and the Internet.

When used in a networked or cloud-computing environment, the computing device 1200 may be connected to a public and/or private network through the network interface 1203. In such embodiments, a modem or other means for establishing communications over the network is connected to the system bus 1201 via the network interface 1203 or other appropriate mechanism. A wireless networking component including an interface and antenna may be coupled through a suitable device such as an access point or peer computer to a network. In a networked environment, program modules depicted relative to the computing device 1200, or portions thereof, may be stored in the remote memory storage device.

Certain embodiments are described herein as including one or more modules. Such modules are hardware-implemented, and thus include at least one tangible unit capable of performing certain operations and may be configured or arranged in a certain manner. For example, a hardware-implemented module may comprise dedicated circuitry that is permanently configured (e.g., as a special-purpose processor, such as a field-programmable gate array (FPGA) or an application-specific integrated circuit (ASIC)) to perform certain operations. A hardware-implemented module may also comprise programmable circuitry (e.g., as encompassed within a general-purpose processor or other programmable processor) that is temporarily configured by software or firmware to perform certain operations. In some example embodiments, one or more computer systems (e.g., a standalone system, a client and/or server computer system, or a peer-to-peer computer system) or one or more processors may be configured by software (e.g., an application or application portion) as a hardware-implemented module that operates to perform certain operations as described herein.

Accordingly, the term “hardware-implemented module” encompasses a tangible entity, be that an entity that is physically constructed, permanently configured (e.g., hardwired), or temporarily configured (e.g., programmed) to operate in a certain manner and/or to perform certain operations described herein. Considering embodiments in which hardware-implemented modules are temporarily configured (e.g., programmed), each of the hardware-implemented modules need not be configured or instantiated at any one instance in time. For example, where the hardware-implemented modules comprise a general-purpose processor configured using software, the general-purpose processor may be configured as respective different hardware-implemented modules at different times. Software may accordingly configure the processor 1202, for example, to constitute a particular hardware-implemented module at one instance of time and to constitute a different hardware-implemented module at a different instance of time.

Hardware-implemented modules may provide information to, and/or receive information from, other hardware-implemented modules. Accordingly, the described hardware-implemented modules may be regarded as being communicatively coupled. Where multiple of such hardware-implemented modules exist contemporaneously, communications may be achieved through signal transmission (e.g., over appropriate circuits and buses) that connect the hardware-implemented modules. In embodiments in which multiple hardware-implemented modules are configured or instantiated at different times, communications between such hardware-implemented modules may be achieved, for example, through the storage and retrieval of information in memory structures to which the multiple hardware-implemented modules have access. For example, one hardware-implemented module may perform an operation, and may store the output of that operation in a memory device to which it is communicatively coupled. A further hardware-implemented module may then, at a later time, access the memory device to retrieve and process the stored output. Hardware-implemented modules may also initiate communications with input or output devices.

Computing systems or devices referenced herein may include desktop computers, laptops, tablets e-readers, personal digital assistants, smartphones, gaming devices, servers, and the like. The computing devices may access computer-readable media that include computer-readable storage media and data transmission media. In some embodiments, the computer-readable storage media are tangible storage devices that do not include a transitory propagating signal. Examples include memory such as primary memory, cache memory, and secondary memory (e.g., DVD) and other storage devices. The computer-readable storage media may have instructions recorded on them or may be encoded with computer-executable instructions or logic that implements aspects of the functionality described herein. The data transmission media may be used for transmitting data via transitory, propagating signals or carrier waves (e.g., electromagnetism) via a wired or wireless connection.

The described methods, processes, operations, and associated actions may also be performed in various orders in addition to the order described in this application, in parallel, and/or simultaneously. The described systems are exemplary in nature and may include additional elements and/or omit elements. Furthermore, references to or “one example” of the present disclosure are not intended to be interpreted as excluding the existence of additional embodiments that also incorporate the recited features. It will be understood that when a certain part or process “includes” a certain component or operation, that part or process does not exclude another component or operation. While illustrative examples of the name screening techniques using phonetic embeddings have been described herein including systems, devices, and the like, it is to be understood that various other adaptations and modifications may be made within the spirit and the scope of the examples herein. Additionally, it is appreciated that while specific graphics are shown and described, such graphics are illustrative and exemplary and are not intended to limit the scope of this disclosure.

The foregoing description has been directed to specific examples. It will be apparent, however, that other variations and modifications may be made to the described examples, with the attainment of some or all of their advantages. For instance, it is expressly contemplated that the components and/or elements described herein can be implemented as software being stored on a tangible (non-transitory) computer-readable medium, devices, and memories (e.g., disks/CDs/RAM/EEPROM/etc.) having program instructions executing on a computer, hardware, firmware, or a combination thereof. Further, methods describing the various functions and techniques described herein can be implemented using computer-executable instructions that are stored or otherwise available from computer readable media. Such instructions can comprise, for example, instructions and data which cause or otherwise configure a general-purpose computer, special purpose computer, or special purpose processing device to perform a certain function or group of functions. Portions of computer resources used can be accessible over a network. The computer executable instructions may be, for example, binaries, intermediate format instructions such as assembly language, firmware, or source code. Examples of computer-readable media that may be used to store instructions, information used, and/or information created during methods according to described examples include magnetic or optical disks, flash memory, USB devices provided with non-volatile memory, networked storage devices, and so on. In addition, devices implementing methods according to these disclosures can comprise hardware, firmware and/or software, and can take any of a variety of form factors. Typical examples of such form factors include laptops, smart phones, small form factor personal computers, personal digital assistants, and so on. Functionality described herein also can be embodied in peripherals or add-in cards. Such functionality can also be implemented on a circuit board among different chips or different processes executing in a single device, by way of further example. Instructions, media for conveying such instructions, computing resources for executing them, and other structures for supporting such computing resources are means for providing the functions described in these disclosures. Accordingly, this description is to be taken only by way of example and not to otherwise limit the scope of the examples herein. Therefore, it is the object of the appended claims to cover all such variations and modifications as come within the true spirit and scope of the examples herein.

In addition, the description of the disclosure is provided to enable a person skilled in the art to make or use the disclosure. Various modifications to the disclosure will be readily apparent to those skilled in the art, and the generic principles defined herein may be applied to other variations without departing from the spirit or scope of the disclosure. Throughout this disclosure the term “example” or “exemplary” indicates an example or instance and does not imply or require any preference for the noted example. Thus, the disclosure is not to be limited to the examples and designs described herein but is to be accorded the widest scope consistent with the principles and novel features disclosed herein.

Additional aspects of this disclosure are set out in the independent claims and preferred features are set out in the dependent claims. Features of one aspect may be applied to each aspect alone or in combination with other aspects. In addition, while certain operations in the claims are provided in a particular order, it is appreciated that such order is not required unless the context otherwise indicates.

What is claimed is:

1. A system implementing a simulation framework to evaluate time varying systems, comprising:
a physical system including at least one sensor and at least one actuator in operable communication via a network; and
a processor in communication with the physical system and configured to evaluate the physical system via implementation of a simulation network, the processor being configured to:
access data from the physical system including a set of traces, each of the set of traces corresponding to a respective configuration and associated output from the physical system,
derive a series of piece wise linear time invariant simulations associated with the set of traces in intervals concatenated in time domain, and
derive time stamps of each simulation of the piece wise linear time invariant simulations such that the simulation error can be kept within pre-specified bounds.

2. The system of claim 1, wherein by implementation of the simulation network the processor evaluates an error bound for piecewise time invariant simulation of the physical system while achieving speed up.

3. The system of claim 1, wherein the framework is configured for the propagation of error in model coefficients through the system dynamics and provide a pathway to derive time stamps.

4. The system of claim 1, wherein the physical system is a wireless network-controlled human-in-the-loop (HIL)—human-in-plant (HIP) system.

5. The system of claim 1, wherein by implementation of the simulation network the processor conducts the series of piece wise linear time invariant simulations until both a trajectory error and a trace error is satisfied by qᵢₙᵥ=Error_Bounded_Invariant_Time(ϵₚ, ψₚ).

6. The system of claim 1, wherein the simulation framework is configured to simulate and evaluate an artificial pancreas wireless network system that controls blood glucose with time varying properties such as physiological changes associated with psychological stress and meal patterns.

7. The system of claim 6, wherein the physical system includes a continuous glucose monitor (CGM) that senses glucose, and a controller that computes insulin delivery which is executed through an infusion pump.
